(19) United States
(12) Patent Application Publication
(10) Pub. No.: US 2025/0293709 A1
(43) Pub. Date: Sep. 18, 2025

(54) SYSTEMS AND METHODS FOR OPTIMIZED REGULAR AND IRREGULAR SD-LDPC CODES FOR 50G-PON/100G-PON AND BEYOND

(71) Applicant: Arizona Board of Regents on Behalf of the University of Arizona, Tucson, AZ (US)

(72) Inventors: Ivan B. Djordjevic, Tucson, AZ (US); Mingwei Yang, Tucson, AZ (US); Ziwen Pan, Tucson, AZ (US)

(21) Appl. No.: 19/080,706

(22) Filed: Mar. 14, 2025

Related U.S. Application Data
(60) Provisional application No. 63/565,438, filed on Mar. 14, 2024.

(51) Int. Cl. H03M 13/11

(52) U.S. Cl. CPC H03M 13/1148; H03M 13/1105

(57) ABSTRACT

The present disclosure relates to systems and methods for FGPA-based burst-error performance and optimization of regular and irregular SD-LDPC codes for 50G-PON/100G-PON and beyond. In particular, the burst-error performance of the regular low-density parity-check (LDPC) code is evaluated and the irregular LDPC code that has been considered for ITU-T's 50G-PON standard via experimental measurements in FPGA. By using intra codeword interleaving and parity-check matrix rearrangement, it is demonstrated that the BER performance can be improved under ˜44-ns-duration burst errors for 50 Gb/s/100 Gb/s upstream signals.

### CROSS REFERENCE TO RELATED APPLICATIONS

The present document is a non-provisional patent application that claims benefit to U.S. Provisional Patent Application Ser. No. 63/565,438 filed on Mar. 14, 2024 which is herein incorporated by reference in its entirety.

### FIELD

The present disclosure generally relates to quantum technologies; and in particular to systems and methods for optimized regular and irregular SD-LDPC codes, among other aspects described herein.

### BACKGROUND

The IEEE 802.3ca 25G-Ethernet Passive Optical Network (EPON) working group has chosen a high-performance hard-decision (HD) irregular LDPC coding-based forward error correction (FEC) scheme with a bit-error ratio (BER) threshold of about 10⁻² and a code rate of 0.849.

LDPC codes are used as one of FEC solutions in optical transmission systems to provide the error correction performance close to the channel capacity. LDPC coding was introduced by Gallager in the early 60's and employ iterative message-passing (MP) decoding algorithms. Such a decoding algorithm exchange the extrinsic information between coded bit nodes and parity-check nodes in which they participate in an iterative fashion. At each new iteration, new messages are computed in an extrinsic manner, which means that the message received by a coded bit node from a parity-check node does not depend on the message just sent to the other nodes in the previous round. Consequently, the collected belief information keeps propagating within each new decoding iteration, which provides a maximum a posteriori probability decoding of the transmitted codeword (when there are no cycles in corresponding bipartite representation of the parity-check matrix).

It is with these observations in mind, among others, that various aspects of the present disclosure were conceived and developed.

### BRIEF DESCRIPTION OF THE DRAWINGS

The present patent or application file contains at least one drawing executed in color. Copies of this patent or patent application publication with color drawing(s) will be provided by the Office upon request and payment of the necessary fee.

FIG. 1A is an illustration of an example field-programmable gate array (FPGA) architecture used for soft-decision low-density parity check (SD-LDPC).

FIG. 1B is a report of utilization % associated with the architecture of FIG. 1A.

FIG. 2A illustrates a graph of different burst-error scenarios.

FIG. 2B is a simulated signal waveform showing a burst-mode errors with non-uniform signal levels.

FIGS. 3A-3C illustrate a series of graphs of the regular LDPC codes performance for different degradations: (a) without intra codeword interleaving, (b) with intra codeword interleaving of 8 pieces, and (c) with intra codeword interleaving of 2 pieces.

FIG. 4 illustrates three parity-check matrix column arrangements of the same LDPC mother code: (a) Hₐ, (b) H_{b}, and (c) H_{c}.

FIGS. 5A-5E illustrate a series of error correction performance curves for different parity-check matrices: (a) Hₐ, (b) H_{b}, (c) H_{c}, (d) intra codeword interleaved case of 8 pieces based on H_{b}, and (e), intra codeword interleaved case of 2 pieces based on H_{b}.

FIG. 6 is a flow chart of an example process and/or method associated with the inventive concept described herein.

Corresponding reference characters indicate corresponding elements among the view of the drawings. The headings used in the figures do not limit the scope of the claims.

### DETAILED DESCRIPTION

The present disclosure relates to systems and methods for FGPA-based burst-error performance and optimization of regular and irregular SD-LDPC codes for 50G-PON, 100G-PON, and beyond. In particular, the burst-error performance of the regular low-density parity-check (LDPC) code is evaluated and the irregular LDPC code that has been considered for ITU-T's 50G-PON standard via experimental measurements in FPGA has been imporved. By using intra codeword interleaving and parity-check matrix rearrangement, it is demonstrated that the bit-error ratio (BER) performance can be improved under ˜44-ns-duration burst errors for 50 Gb/s/100 Gb/s upstream signals.

### 1. Introduction

The IEEE 802.3ca 25G-EPON working group has chosen a high-performance hard-decision (HD) irregular LDPC coding-based forward error correction (FEC) scheme with a bit-error ratio (BER) threshold of about 10⁻² and a code rate of 0.849. During the standard meeting, the use of soft-decision (SD) was proposed to improve the performance of the irregular LDPC mothercode that has been specified by the IEEE working group in order to better support 50G-PON. The SD-LDPC performance has been analyzed via real-time measurements with field programmable gate array (FPGA), showing that SD-LDPC outperforms HD-LDPC by over 1 dB in terms of the gross coding gain at an output BER of 10⁻¹². More recently, the International Telecommunication Union (ITU) had consented ITU-T 50G-PON standard to support disruptive application and services including the high-definition (HD) video streaming service, virtual/mixed reality, online video meeting, cloud storage and computing. The standard adopted the same LDPC mother code as IEEE 802.3ca with slightly different puncturing and shortening.

LDPC codes are widely used as one of FEC solutions in optical and wireless transmission systems to provide the error correction performance close to the channel capacity. LDPC coding was introduced by Gallager in the early 60's and employ iterative message-passing (MP) decoding algorithms. Such a decoding algorithm exchange the extrinsic information between coded bit nodes and parity-check nodes in which they participate in an iterative fashion. At each new iteration, new messages are computed in an extrinsic manner, which means that the message received by a coded bit node from a parity-check node does not depend on the message just sent to the other nodes in the previous round. Consequently, the collected belief information keeps propagating within each new decoding iteration, which provides a maximum a posteriori probability decoding of the transmitted codeword (when there are no cycles in corresponding bipartite representation of the parity-check matrix). There are various approaches to implement the MP algorithm.

As described herein, the inventive disclosure utilizes aspects of the scaled min-sum algorithm. Irregular LDPC codes are proposed by Luby et al. that can approach capacity more closely than regular ones by proper parity-check matrix construction (M. Luby, M. Mitzenmacher, A. Shokrollahi, and D. Spielman, “Improved low-density parity-check codes using irregular graphs,” IEEE Trans. Inform. Theory 47 (2), 585-598 (2001)). The density evolution theory is developed by Richardson et al. to analyze and synthesize optimal degree distributions in asymptotically large random bipartite graphs under a wide range of channel realizations (T. J. Richardson, M. A. Shokrollahi, and R. L. Urbanke, “Design of capacity-approaching irregular low-density parity-check codes,” IEEE Trans. Inform. Theory 47 (2), 619-637 (2001)).

In a time-division-multiplexed (TDM) passive optical network (PON), burst-mode (BM) operation is an essential feature for upstream communication. During the transmission, the optical performance at the beginning portion of each upstream signal burst is usually much worse than that of the rest of the burst, which can lead to burst errors during the beginning portion of the stream. The performance degradation at the beginning of each upstream signal burst is typically introduced by several impairment sources, such as the electrical and optical turn-on transients of the transmitter and the receiver. It is important to evaluate the burst-error performance of FEC for upstream transmission in TDM-PON.

The present inventive concept described herein analyzes the burst errors mode for the 50G-PON standard based on the non-uniformly distributed errors model. Then, a commercial irregular LDPC code studied is implemented and tested and compare it against regular LDPC code performance under the burst mode errors. By using parity-check matrix rearrangement and different intra codeword interleaving, it is observed that both regular LDPC code and irregular LDPC code performance would be improved under burst mode errors by using the proper optimization. For both regular LDPC code and irregular LDPC code, the intra codeword interleaving with the accurate knowledge of burst mode errors duration will provide the optimal correction performance. However, it will lead to the extra costs of latency and buffering resources. For the irregular LDPC code, the suboptimal option is to rearrange its parity-check matrix. In under this method of the present disclosure, improvements were realized to the coding performance around 0.3 dB without the extra cost of latency and buffering resources under burst mode errors. This method could provide an interesting approach to be considered for the next generation 100G-PON standard.

The remainder of the present disclosure is organized as follows. In Section 2, an example system model is described, including the FPGA architecture and the non-uniformly distributed errors model in the burst mode. In Section 3, the disclosure details disclosure of an implemented regular LDPC code and its performance is analyzed on different scaled burst mode errors with and without intra codeword interleaving. Section 4 is devoted to the performance analysis of the implemented commercial standard irregular LDPC code performance under burst error mode by using parity matrix rearrangement and intra codeword interleaving. Both modelling analysis and FPGA verification were conducted for different burst errors mode level. Finally, Section 5 summarizes and provides example non-limiting conclusions.

### 2. FPGA Architecture and Burst Errors Model

For the on-of keying (OOK) or binary phase-shift keying (BPSK) transmission over thermal or amplified spontaneous emission (ASE) noise dominated channel, which could be considered as an additive white Gaussian noise (AWGN) channel, let the log likelihood ratio (LLR) information of the i-th received symbol yᵢ be represented by δᵢ and it is defined by:

$${δ}_{i} = log ( \frac{P r ( {x}_{i} = 0 \vert {y}_{i} )}{P r ( {x}_{i} = 1 \vert {y}_{i} )} ) \qquad ( 1 )$$

where the prior probabilities of the transmitted bit of 0 and 1 are equal, xᵢ represents the i-th transmitted bit, and Pr(xᵢ=0 |yᵢ) represents the posterior probability of the i-th transmitted symbol xᵢ given the received symbol yᵢ. For LDPC decoder under the binary input AWGN channel, let σ² represents the noise variance. βᵥ^{k,l} and αᵥ^{k,l} represent extrinsic information (message) at the variable v and the check c at k-th iteration and l-th layer message, β_{cv}^{k,l} and α_{vc}^{k,l} represent the check c to variable v extrinsic information (message) and the variable v to check c at k-th iteration and l-th layer message; where l=1, . . . , L and k=1, . . . , Iₘₐₓ. The parameters Iₘₐₓ and L denote the maximum iteration index and layer index, respectively. The FPGA processors can be summarized through Eqs. (2)-(5) provided below:

$${δ}_{i} = \frac{2}{{σ}^{2}} {y}_{i} \qquad ( 2 )$$

$${α}_{v}^{k , l} = {δ}_{i} + {\sum }_{{l}^{′}} {β}_{c v}^{k , {l}^{′}} \qquad ( 3 )$$

$${α}_{v c}^{k , l} = {δ}_{i} + {\sum }_{{l}^{′} \neq l} {β}_{c v}^{k , {l}^{′}} \qquad ( 4 )$$

$${β}_{v}^{k , l} = s \times {\prod }_{{v}^{′} \neq v} sign ( {α}_{{v}^{′} c}^{k , l} ) {min}_{{v}^{′} \neq v} \vert {α}_{{v}^{′} c}^{k , l} \vert \qquad ( 5 )$$

where s represents the scaling factor for the scaled min-sum algorithm. Equation (2) is employed to calculate the bit LLR in OOK/BPSK AWGN channel and Eqs. (2)-(5) are used in the layered decoding algorithm.

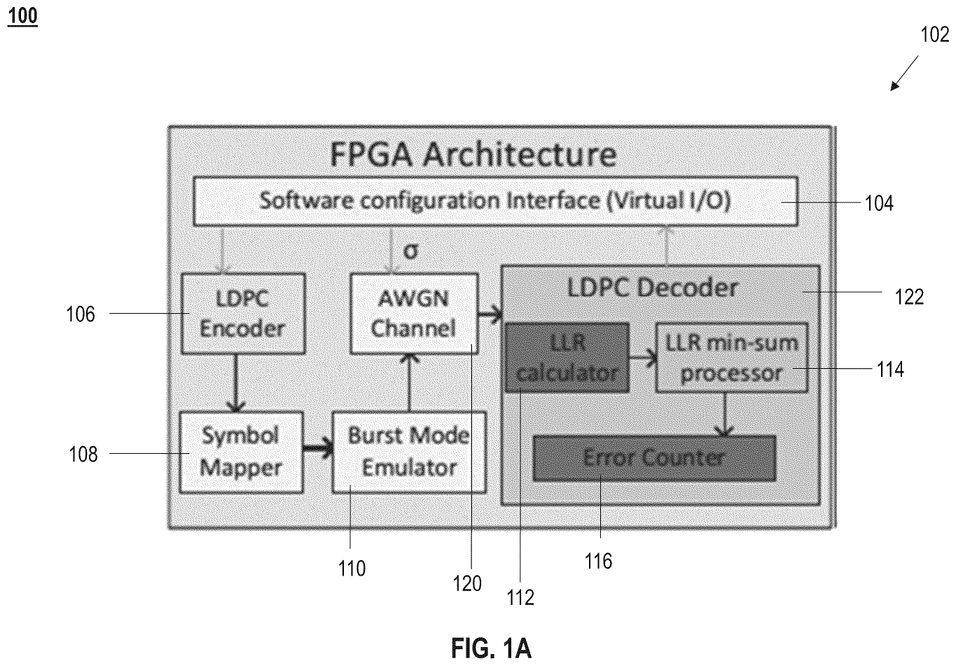

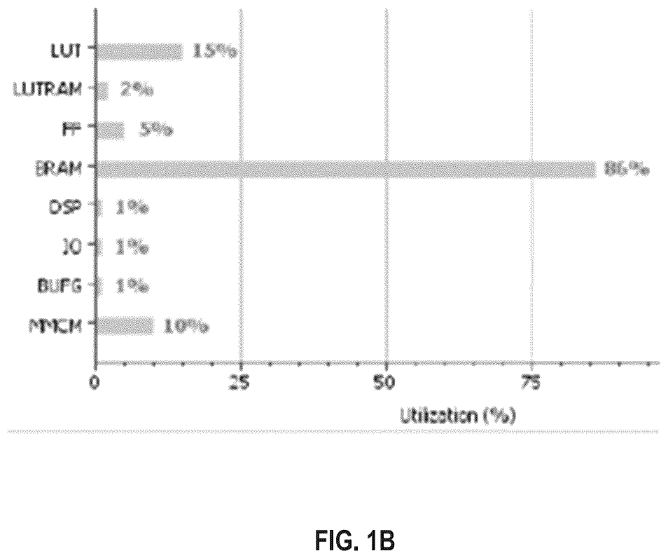

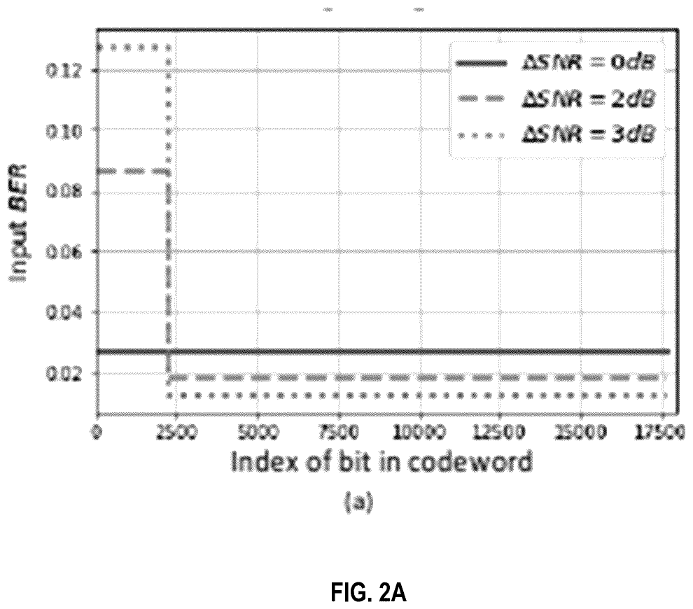

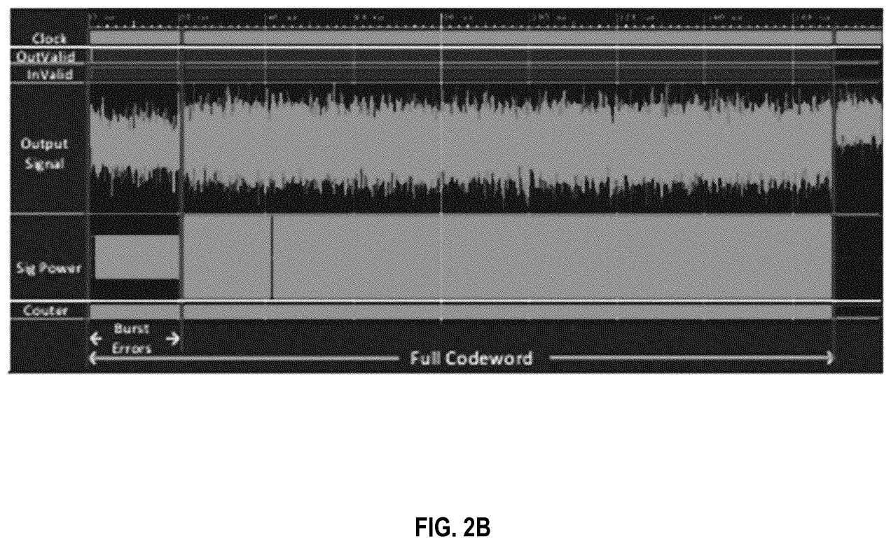

Referring to FIG. 1(a), an example design architecture or platform 100 for an FPGA based real-time low-density parity-check (LDPC) emulator (102) is illustrated that can be designed and implemented, with corresponding utilization of FPGA resources provided in FIG. 1(b). The platform 100 includes the following parts: a software configuration interface 104, an LDPC encoder 106; a modulation symbol mapper 108, a Gaussian noise generator (not shown), a burst error emulator 110, an LLR calculator 112, a rate-adaptive LLR processor 114 based on layered scaled min-sum algorithm; and an error counter circuit 116. The LDPC encoder 106 produces a sequence of binary encoded codeword, which consists of information bits and parity-check bits. A read only memories (ROMs) based modulation mapper is responsible to generate signed symbols based on input binary codeword sequence and sent to a burst errors' emulator. The first ⅛ portion of each codeword were attenuated before transmitting over an AWGN channel (120) to emulate the burst errors. A PC can control the attenuation factor through the software configuration interface 104. Based on the Box-Muller algorithm, the Gaussian noise generator generates samples of the white Gaussian noise by using two linear-feedback shift register (LFSR) based uniform generators. The generated sequence of samples is multiplied with standard deviation of noise o to emulate the output signals from AWGN channel. The signal and the noise are both 32 bits with 25 bits fractional parts. Based on Eq. (1), the emulated output signals are sent to the LLR calculator 112 to calculate the bit LLR. Then the quantized bit LLR is obtained based on Eq. (2) and fed to the LDPC decoder 122 based on Eqs. (3)-(5). In LLR min-sum processor 114, we optimize the power and latency cost by compressing the input axe into a smaller size after deleting the unnecessary nodes. In order to check whole variable nodes BER values within one layer, we delayed and inserted corresponding unnecessary nodes value to the output of the min module β_{cv}^{k,l′} into the full size. The location of the unnecessary α_{vc}^{k,l} and non-updated βᵥ^{k,l′} are controlled by a finite state machine. In the architecture, the noise variance, the number of iterations, the burst error attenuation factor, and the length of shortening are controlled by the Virtual I/O based software controlled interface (104). The software control interface also reports the number of errors and the number of codewords to calculate the BER. A full codeword monitoring result are depicted at the FIG. 2(b). The row of output signal is the binary signal under AWGN channel emulated at FPGA. The row of signal power is the binary signal transmitted before the AWGN channel. The first ⅛ portion of the codeword shows lower amplitude both in the row of output signal and the row of signal power.

In PON, each upstream burst usually experiences more burst errors at the beginning of the burst. Typically, it is desirable to limit the time duration of the burst-error region to <100 ns. In the burst-error region, the input BER to the FEC decoder at the upstream receiver may be much higher than the average input BER. In the burst mode upstream TDM PON, the burst transmission consists of a preamble used for synchronization and the data encoded with LDPC. By using different size of the preamble, the impact of the burst errors from the channel will also vary. The length of the preamble is normally short (˜128 bits) compared to the length of the burst duration (more than 2000 bits). Adding few bits to the preamble will significantly improve the performance of the signal synchronization, therefore, in this disclosure, one focus is on the solution of the fixed length of the preamble solution for the burst errors case without considering of the impact of the burst noise on the signal frame synchronization.

To emulate the non-uniform burst error behavior, the burst errors module intentionally introduces more errors in the first ⅛ portion of each LDPC codeword, which corresponds to about 44 ns for a 50-Gbps upstream signal, 88 ns for a 25-Gbps upstream signal, or 22 ns for a 100 Gb/s upstream signal. To emulate different degrees of bit error non-uniformity, we introduce different signal-to-noise (SNR) degradations for the burst-error region w.r.t. the steady-power region. To generate the SNR degradation in the burst-error region, we reduce the power level. More specifically, we attenuate the power of the first ⅛ of each codeword frame by various amounts such as 0 dB, 2 dB, and 3 dB, respectively corresponding to the reduced power levels of 1.0, 0.63, and 0.5, which are normalized to the steady-state power level. The reduced power level of 1.0 indicates burst mode without errors. An illustrative example of the input BER distribution with the same average input BER and different attenuation values is provided in FIG. 2(a). These three cases of attenuation 0 dB, 2 dB, and 3 dB are labeled with ΔSNR =0 dB, ΔSNR=2 dB, and ΔSNR=3 dB respectively. The first ⅛ bits of the 2 dB- and 3 dB-attenuation cases lead to the input BERs of 0.0868 and 0.1273, respectively. The following ⅞ bits of the 2 dB- and 3 dB-attenuation cases yield to the input BERs of 0.0185and 0.0127. Considering the whole codeword, they all provide the overall input BER of 0.027 in average. At the decoder, we use the same variance to calculate the LLR since it is more practical in the real system. A more accurate variance, especially when used for calculate the LLR for the burst error region, will definitely improve the decoding performance; however, it will increase the variance estimation complexity and thus energy cost of the real-time system will increase as well. Clearly, the scenario in which the first ⅛ bits of a codeword get attenuated is expected to exhibit higher input BER at first ⅛ of codeword bits. However, in the non-uniform attenuation scenario the situation gets changed as follows. To achieve the same average input BER, the steady-state ⅞ codeword bits must have lower input BER so that overall average BER is the same as for the uniform case. Viewed from the decoder point of view, the first ⅛ of variable nodes will provide less belief information while the following ⅞ variable nodes will provide higher belief information. Emulated by Xilinx Vivado, the time-domain waveform of a representative output signals from AWGN channel is shown in FIG. 2(b). The inValid and outValid signals enable the input port and output port, respectively. SigPower describes the input signals affected by the burst errors. Output Signal waveform illustrates the attenuated output signal in the presence of AWGN.

When the noise is uniformly distributed in the transmission channel, the variable nodes with higher column weight in a well-designed irregular LDPC codes will collect more belief information in one iteration since the corresponding variable nodes are connected to more check nodes. Therefore, the irregular LDPC codes will provide higher coding gain since the irregular LDPC codes would converge faster than regular LDPC codes. However, in the burst mode, the errors are distributed non-uniformly. The non-uniformly distributed errors lead to the different convergence speed in the regular LDPC codes. There naturally arises the question, whether the performance of the regular LDPC codes will be still better in this case? Can the performance of the irregular LDPC codes be optimized based on the error distribution? Based on our FPGA system, we will answer the first question in the Section 3 and the second one in the Section 4.

### 3. Regular LDPC Performance Under Burst Mode Errors

Based on the FPGA system in FIG. 1(a), an implementation was made of a regular LDPC code constructed based on the same method with the codeword length of 16935, information bits length of 13550, code rate of 0.8, column weight of 3, row weight of 15, and the girth of 8. The burst errors are concentrated at the first ⅛ of each codeword (due to a SNR degradation of up to 3 dB), corresponding to ˜44 ns (˜88 ns) for a 50-Gbps (25-Gbps) upstream signals. The employed decoder has three layers and employs 24 iterations. The purpose is to study the suitability of the regular LDPC code for the burst-mode upstream reception operation in the 50G-PON. We use the Xilinx Kintex UltraScale FGPA KCU105 with 530 logic cells and 1920 DSP slices, 21.1 Mb block RAM as the hardware platform for the implementation. To evaluate the regular LDPC performance, the AD9680 was employed with the sampling wide bandwidth analogy signals of up to 2 GHz to sample the analog signal and perform the quantization, and the AD9144 with more than 1 GHz bandwidth to perform the digital-to-analog conversion.

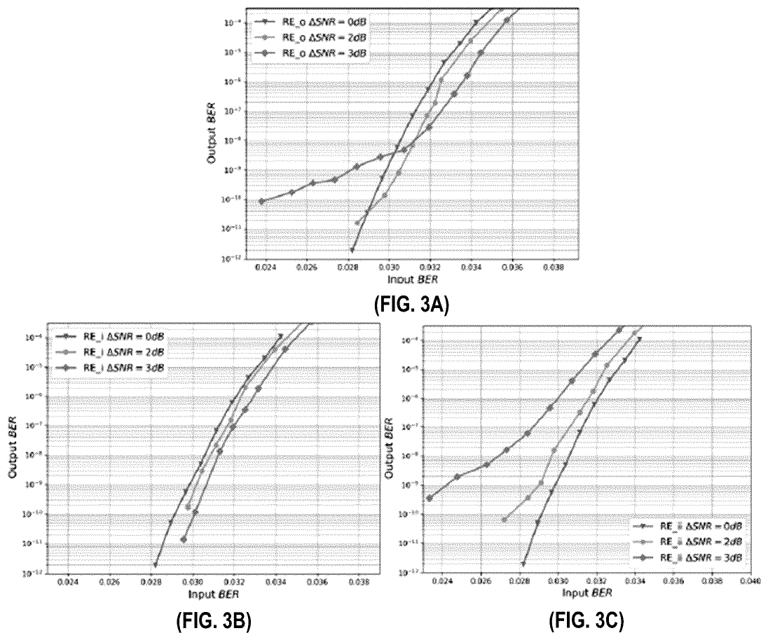

Using the three layered and 24 iterations decoder with 8 bits α_{vc}^{k,l} and β_{cv}^{k,l′} with 5 integer bits, 2 fraction bits and 1 bit for sign, the performance of the code is depicted at FIG. 3(a) with the label of RE_o ΔSNR=m dB, where m represents the value of SNR difference (and RE stands for regular). It was found that although the performance of the regular LDPC code is slightly improved before the output BER of 10⁻⁵ under the non-uniformly distributed burst mode errors, the performance is much worse and even exhibit an error floor when we set the output BER threshold to 10⁻¹⁰. For high SNR condition, the continuous errors in the first ⅛ variable nodes impact the coding performance heavily. This does not represent a surprise, given that from coding theory we know that in burst mode the interleaving is required. We also test the performance of the regular LDPC code after using intra codeword interleaving of 8 pieces, with corresponding results provided in FIG. 3(b), where the label is denoted by RE_i ΔSNR=m dB. In this case, the codeword x=[x₀x₁x₂ . . . xₙ₋₁], where n is the codeword length, will be interleaved as [x₀x₈x₁₆ . . . x₁x₉x₁₇ . . . x_{8q+r-1}], where q is the integer floored quotient of n divided by 8, r is the remainder, n=8*q+r. Instead of only first ⅛ codeword bits suffering heavier noise, only one from every eight bits in a codeword suffer heavier noise. For an LDPC output BER of 10⁻⁹, RE_i ΔSNR=3 dB, RE_i ΔSNR=2 dB, and RE_i ΔSNR=0 dB require the input BER to be 3.07×10⁻² (corresponding to a Q-factor value of 5.44 dB), 3.01×10⁻² (5.48 dB), and 2.97×10⁻² (5.51 dB), respectively. Also implemented and tested was the case of intra codeword interleaving of two pieces whose results are summarized in FIG. 3(c) with the label of RE_ii ΔSNR=m dB. In the case of interleaving of two pieces, each codeword is sliced into 2 pieces first and interleaved with each other. Only one from every two bits at the ¼ beginning of each codeword suffers heavier noise. The results indicate that the performance of the regular LDPC codes can be improved under non-uniformly distributed burst mode errors, which is a positive answer to the first question. However, based on the results of interleaving of two pieces, the optimal improvement requires the accurate knowledge of the duration of the burst mode errors.

By analyzing the LDPC code performance as a function of the input of pre-FEC BER, and the output of post-FEC BER, the FGPA performance results were compared from the regular LDPC code with or without different interleaving strategies under the burst error channel. The results indicate that 12.5% (⅛) of the codeword are in the burst mode channel. Smaller LLRs magnitudes on average bring less belief information compared to the rest of codeword in burst mode free sub-channel. The 87.5% bits in codeword in burst error free sub-channel have higher belief information, and these variable reliabilities help decoding process. Besides, based on the performance of the RE_o ΔSNR=3 dB, the error floor location will increase as suffering the non-uniformly distributed errors. By using the interleaving, which will reallocate the errors distribution in a uniformly method, the error floor will decrease and the coding performance will improve again.

### 4. Irregular LDPC Codes' Performance

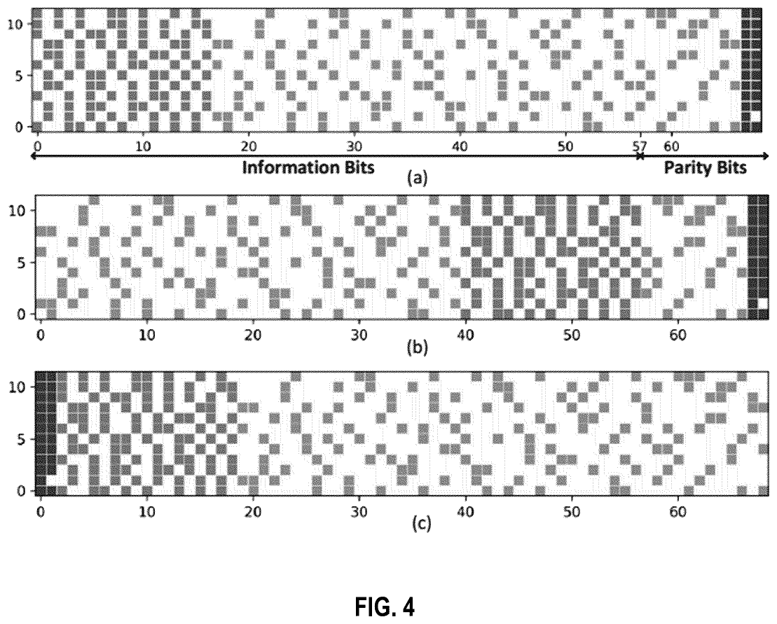

To study the irregular LDPC code performance in non-uniformly distributed errors, an irregular LDPC code mother matrix adopted in ITU-T's 50G-PON standard is implemented on the FPGA platform. FIG. 4(a) illustrates the mother code parity-check matrix Hₐ structure of the irregular LDPC where the colored-box denotes the permutation matrix. It consists of 17664 codeword bits, 14592 information bits, and the code rate is 0.846. The Hₐ matrix consists of three kinds of column blocks with different column weights of 3, 6, 11, and 12. The information bits contain the column of column weight of 3 and 6. The parity check bits contains the column of column weight of 3 and 11 or 12. Since the performance of the irregular codes is impacted by different column weights, we rearrange the Hₐ such that the columns with the lowest weight (3) appear first in order for the code to become more tolerant to burst errors occurring at the beginning of the codeword. The rearranged matrix is organized as follows: H_{b}(1:69)=[Hₐ(18:57), Hₐ(1:17), Hₐ(58:69)], and it is depicted in FIG. 4(b). The original 12 columns of parity checks are unchanged to make the decoding complexity unaffected. To explore the worst-case burst-mode performance, another H-matrix (H_{c}) is rearranged in the opposite way where H_{c}(1:69)=[Hₐ(68:69), Hₐ (1:67)], and it is depicted in FIG. 4(c).

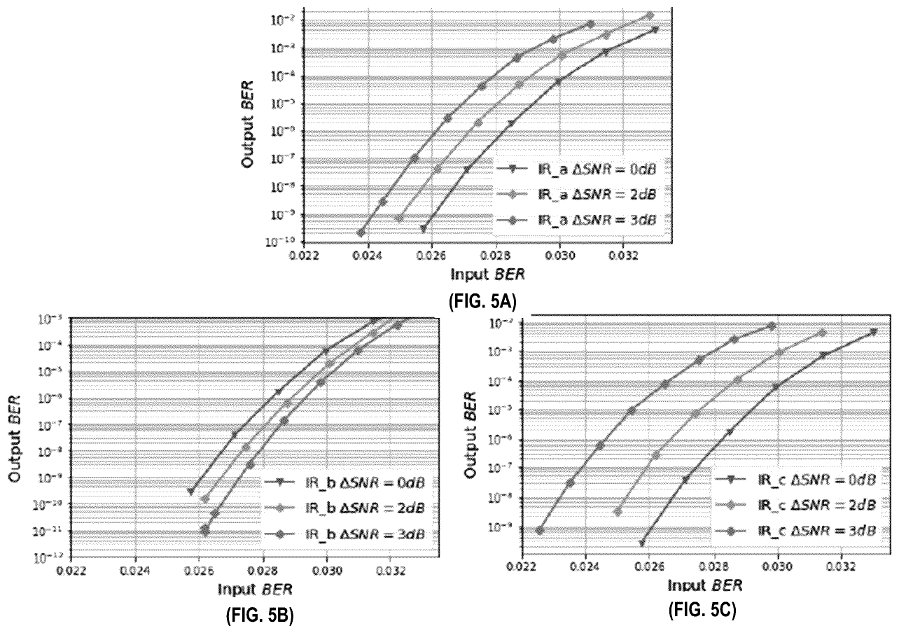

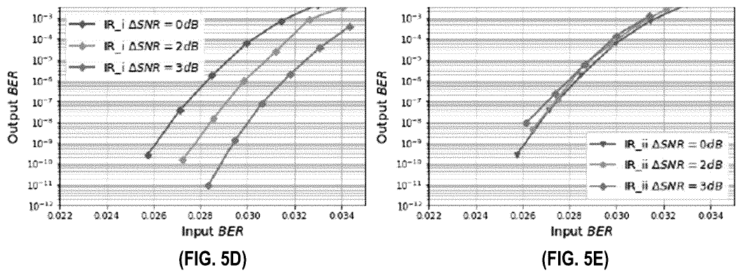

Based on the FPGA system in FIG. 1(a), using the 8 bits α_{vc}^{k,l} and β_{cv}^{k,l′} with 5 integer bits, 2 fraction bits and 1 bit for sign, we implemented LDPC codes with these three parity-check matrices and test their coding performance by employing a decoder with 12 layered and 15 iterations. To compare with the interleaving case, we also test the performance of same two interleaving methods with the ones we use for regular LDPC code in Section 3 based on the H_{b} only. The performance improvement of the interleaving method with the Ha and He will be a similar trend as the case of H_{b}. The results are labeled with 1R_n ΔSNR=m dB, where n=a for the performance of Hₐ, b for the performance of H_{b}, c for the performance of H_{c}, n=i for the performance of interleaved case of 8 pieces, and n=ii for the performance of interleaved case of 2 pieces respectively. In FIG. 5(a), corresponding to an LDPC decoder output BER of 10⁻⁹, IR_a ΔSNR=3 dB, IR_a ΔSNR=2 dB, and IR_a ΔSNR=0 dB require the input BERs to be 2.42×10⁻² (corresponding to a Q-factor value of 5.91 dB), 2.51×10⁻² (5.84 dB), and 2.60×10⁻² (5.77 dB), respectively. Compared to the regular LDPC code without interleaving we tested in Section 3, the irregular LDPC code matrix Ha performances are well maintained (within ˜0.2 dB) for non-uniform input bit error distributions where the errors are concentrated at the first ⅛ of each codeword due to an SNR (or power) reduction of up to 3 dB. The water fall shape is also well maintained for different burst mode errors scales. The performance of regular LDPC code is slightly better than irregular LDPC code due to its lower code rate, when interleaving is used. The irregular structure of the quasi-cyclic (QC) code helps us to effectively combat the burst errors by belief propagation variation. With layered decoding, the a posteriori probability for those affected bits by upstream burst can be improved layer-by-layer from check-node-to-variable-node and variable-node-to-check-node information exchange in the iteration process. Therefore, the ⅛ of affected bits in one codeword can be corrected with very little penalty. However, unfortunately, the performance of the Hₐ decrease when suffering higher burst mode errors. Based on the result from Section 3, we know that it is possible to have higher coding performance for the non-uniformly distributed burst errors channel model. By comparing the FIGS. 5(a)-(e), the interleaving of 8 pieces method provides the best performance. For an LDPC output BER of 10⁻⁹, IR_i ΔSNR=3 dB, IR_i ΔSNR=2 dB, and IR_i ΔSNR=0 dB requires the input BERs to be 2.95×10⁻² (corresponding to a Q-factor value of 5.52 dB), 2.78×10⁻² (5.64 dB), and 2.60×10⁻² (5.77 dB), respectively. Compared to the case of IR_i ΔSNR=0 dB, the case of IR_i ΔSNR=3 dB improves the Q-factor by ˜0.25 dB after suffering the non-uniformly distributed errors with 3 dB SNR (or power) reduction. Compared to the case of IR_a ΔSNR=3 dB, the improvement from the case of IR_i ΔSNR=3 dB is around 0.45 dB. However, the method of interleaving of 8 pieces requires the exact knowledge of the burst mode errors duration and rearranging bits instead of blocks. The results of the interleaving case of 2 pieces, depicted at FIG. 5(e), indicate the little improvement, thus supporting this observation. Rearranging or interleaving bits will not maintain the cyclic shift block structure of the parity check matrix. It leads to extra energy and latency cost at encoder and also increases the complexity of the decoder design. The second best performance comes from the rearranged matrix H_{b}-For the output BER threshold of 10⁻⁹, IR_b ΔSNR=3 dB, IR_b ΔSNR=2 dB, and IR_b ΔSNR=0 dB require the input BERs to be 2.72×10⁻² (corresponding to a Q-factor value of 5.68 dB), 2.67×10⁻² (5.72 dB), and 2.60×10⁻² (5.77 dB), respectively. Compared to the case of IR_b SNR=0 dB, the performance of the matrix H_{b} improves the Q-factor by ˜0.1 dB after suffering the non-uniformly distributed errors with 3 dB SNR (or power) reduction. Compared to the case of IR_a ΔSNR=3 dB, the improvement from the case of IR_b ΔSNR=3 dB is around 0.3 dB. Compared to the parity-check matrix Hₐ, the parity-check matrix H_{b} is derived by cyclic shift of the columns in information bits of the Hₐ-matrix. It will not cost extra latency and complexity when implementing in FPGA/ASIC. The reason of the improvement coming from H_{b}-matrix is that the lower column weight at beginning of the codeword that suffers more impairments get involved in smaller number of check nodes in decoding process and vice versa for the higher column weights at the ending portion of the H-matrix. The FPGA emulations corresponding to the H_{c}-matrix, depicted at FIG. 5(c), indicate the worst BER performance, thus supporting this observation. There are many combinations for arranging the parity-check matrix to get a better burst error performance. Reversing the information related columns is another choice. Also, because the burst mode is a well-defined, as long as we move some low weight columns to the left, we will get some benefit. Therefore, the answer for the second question would be: by rearranging the parity-check matrix of the irregular LDP code by matching the lower column weight to the bits in burst mode it is possible to get better coding performance under the burst error channel model introducing the non-uniformly distributed errors, without extra cost for interleaving codewords.

### 5. Example (non-limiting) Conclusions

We have evaluated the error-correction performance of the regular LDPC code under the burst mode errors with and without interleaving in PON scenario. We also evaluated the performance of the rearranged and interleaved irregular LDPC code that was under study by ITU-T's 50G-PON group for burst mode upstream reception operation. Real-time measurements have been done by using the Ultrascale FPGA. It has been found that without using interleaving, the regular LDPC code performance get affected tremendously for non-uniform input bit error distributions, where the errors have been concentrated at the first ⅛ of each codeword (due to a SNR degradation of up to 3 dB), corresponding to ˜44 ns (˜88 ns) for a 50-Gbps (25-Gbps) upstream signals. In the same condition, the irregular LDPC code performance has been well maintained and can be noticeably improved by properly rearranging the columns of its parity-check matrix such that the beginning parity-check matrix columns have the smallest weight (of 3). Although properly interleaved regular LDPC code and irregular LDPC code both provide excellent performance, this approach brings extra energy and latency cost and require the knowledge of accurate burst mode errors duration in advance. Compared to the interleaving, the rearrangement design improvement can be obtained without affecting the complexity or latency of the LDPC encoder and decoder, making it beneficial for 50G-PON (and possibly 100G-PON) burst-mode upstream transmission for the next-generation optical access networks. Thus, the LDPC design described in [4-8] can be potentially improved by rearrangement for both downstream and upstream transmissions in TDM-PON, and may find valuable applications in future broadband fiber access networks such as 50G-PON, 100G-PON and beyond.

Other potential applications include: turbulent free-space optical communications, turbulent underwater communications, wireless communication in congested environment, wireless communication in the presence of jammer, to mention few.

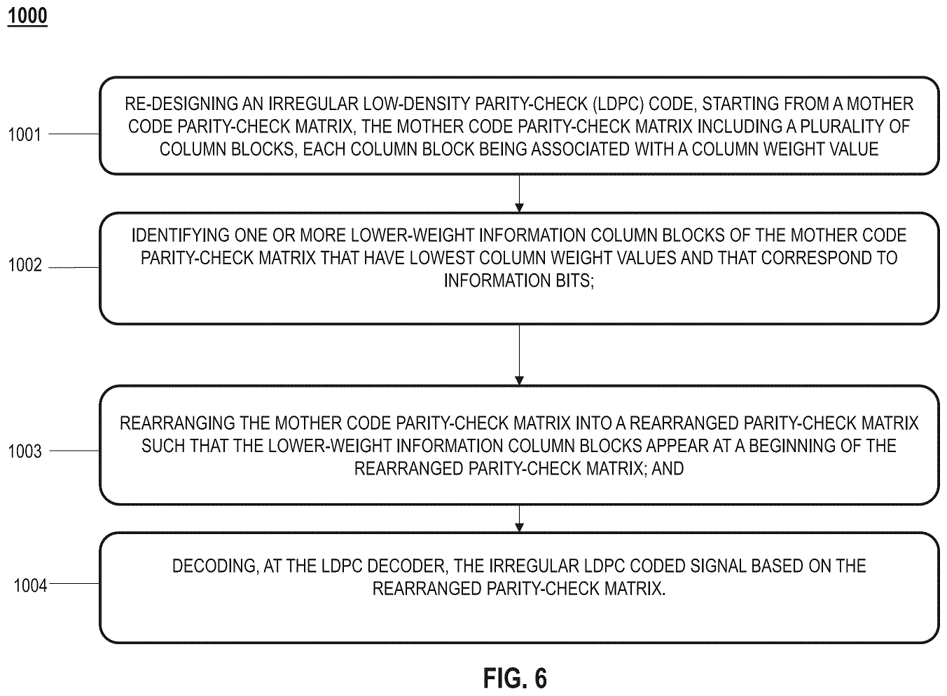

FIG. 6 depicts an example non-limiting process 1000 associated with the inventive concept described herein, including blocks 1001-1004. The DPC decoder can leverage a low complexity decoding procedure for irregular LDPC codes; as described by Eqs. (1)-(5), with the decoding architecture provided in FIG. 1A.

It should be understood from the foregoing that, while particular embodiments have been illustrated and described, various modifications can be made thereto without departing from the spirit and scope of the invention as will be apparent to those skilled in the art. Such changes and modifications are within the scope and teachings of this invention as defined in the claims appended hereto.

What is claimed is:

1. A method, comprising:
re-designing an irregular low-density parity-check (LDPC) code, starting from a mother code parity-check matrix, the mother code parity-check matrix including a plurality of column blocks, each column block being associated with a column weight value;
identifying one or more lower-weight information column blocks of the mother code parity-check matrix that have lowest column weight values and that correspond to information bits;
rearranging the mother code parity-check matrix into a rearranged parity-check matrix such that the lower-weight information column blocks appear at a beginning of the rearranged parity-check matrix; and
decoding, at a LDPC decoder, the irregular LDPC coded signal based on the rearranged parity-check matrix.

2. The method of claim 1, the lower-weight information column blocks of the rearranged parity-check matrix corresponding to bits at a beginning portion of the LDPC coded signal that are subjected to a burst-mode operation.

3. The method of claim 1, wherein compared to the interleaving, the rearrangement design provides improvement without affecting the complexity or latency of the LDPC encoder and decoder, making it beneficial for 50G-PON and 100G-PON burst-mode upstream transmissions for the next-generation optical access networks.

4. The method of claim 1, wherein decoding at the LDPC decoder utilizes a low complexity decoding procedure for irregular LDPC codes, including:
calculating at an LLR calculator a bit LLR; and
obtaining a quantitized bit LLR; and
feeding the quantitized bit LLR to the LDPC decoder.

5. The parity-check matrix of regular LDPC code has been modified by the parity-check matrix rearrangement and proposed intra codeword interleaving, which leads to the improved LDPC code performance in the burst error mode regime.

6. The method of claim 5, wherein the knowledge of burst mode errors duration is utilized in intra codeword interleaving to provide the optimal error correction performance.

7. The method of claim 5, wherein the knowledge of burst mode errors duration is utilized in intra codeword interleaving to eliminate the error floor phenomenon.
